(19) United States
(12) Patent Application Publication
(10) Pub. No.: US 2025/0118668 A1
(43) Pub. Date: Apr. 10, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Yun Cheol HAN, Gyeonggi-do (KR); Hye In YEOM, Gyeonggi-do (KR)

(21) Appl. No.: 18/540,874

(22) Filed: Dec. 15, 2023

(30) Foreign Application Priority Data
Oct. 4, 2023 (KR) 10-2023-0131563

(51) Int. Cl. H01L 23/528; H01L 23/522; H10B 41/10; H10B 41/27; H10B 43/10; H10B 43/27

(52) U.S. Cl. CPC H01L 23/5283; H01L 23/5226; H10B 41/10; H10B 41/27; H10B 43/10; H10B 43/27

(57) ABSTRACT

A semiconductor device may include a first gate structure including stacked first selection lines, each first selection line including a first cell region and a first pad region adjacent in a first direction, a second gate structure including stacked second selection lines, each second selection line including a second cell region and a second pad region adjacent in the first direction, first contact plugs extending through the first pad region and respectively connected to the first selection lines, and second contact plugs extending through the second pad region and respectively connected to the second selection lines, and in a second direction crossing the first direction, the first pad region may have a width greater than that of the first cell region, and the second pad region may have a width greater than that of the first pad region.

### CROSS-REFERENCE TO RELATED APPLICATION

This application claims priority under 35 U.S.C. § 119 to Korean Patent Application No. 10-2023-0131563 filed on Oct. 4, 2023, which is incorporated herein by reference in its entirety.

### BACKGROUND

### 1. Technical Field

The present invention disclosure relates generally to an electronic device, and more particularly, to a semiconductor device and a method of manufacturing the semiconductor device.

### 2. Related Art

An integration degree of a semiconductor device is mainly determined by an area occupied by a unit memory cell. Recently, as improvements in the integration degree of two-dimensional semiconductor devices in which memory cells are formed in a single layer on a substrate reach a limit, three-dimensional (3-D) semiconductor devices in which memory cells are stacked in multiple levels over a substrate have being proposed. Currently, extensive research efforts are expended for developing 3-D semiconductor devices with improved operation reliability and for improving their methods of manufacturing.

### SUMMARY

According to an embodiment of the present invention disclosure, a semiconductor device may include a first gate structure including stacked first selection lines, each first selection line including a first cell region and a first pad region adjacent in a first direction, a second gate structure including stacked second selection lines, each second selection line including a second cell region and a second pad region adjacent in the first direction, first contact plugs extending through the first pad region and respectively connected to the first selection lines, and second contact plugs extending through the second pad region and respectively connected to the second selection lines, and in a second direction crossing the first direction, the first pad region may have a width greater than that of the first cell region, and the second pad region may have a width greater than that of the first pad region.

According to an embodiment of the present invention disclosure, a semiconductor device may include gate lines, first selection lines stacked on the gate lines, dummy selection lines stacked on the gate lines, an isolation structure disposed between the first selection lines and the dummy selection lines and extending into an uppermost gate line among the gate lines, first contact plugs extending into the first selection lines at different depths and respectively connected to the first selection lines, third contact plugs extending through the dummy selection lines and respectively connected to the gate lines, and a fourth contact plug extending through the first selection lines and connected to the uppermost gate line.

### BRIEF DESCRIPTION OF THE DRAWINGS

FIGS. 1A and 1B are diagrams illustrating a structure of a semiconductor device according to an embodiment of the present invention disclosure.

FIGS. 2A and 2B are diagrams illustrating a structure of a semiconductor device according to an embodiment of the present invention disclosure.

FIGS. 3A to 3C are diagrams illustrating a structure of a semiconductor device according to an embodiment of the present invention disclosure.

FIG. 4 is a diagram illustrating a structure of a semiconductor device according to an embodiment of the present invention disclosure.

FIGS. 5A and 5B are diagrams illustrating a structure of a semiconductor device according to an embodiment of the present invention disclosure.

FIG. 6 is a circuit diagram illustrating a cell array structure of a semiconductor device according to an embodiment of the present invention disclosure.

### DETAILED DESCRIPTION

An embodiment of the present invention disclosure provides a semiconductor device and a method of manufacturing the semiconductor device having a stable structure and improved characteristic.

An integration degree of a semiconductor device may be improved by stacking memory cells in a three dimension. In addition, a semiconductor device with a stable structure and improved reliability may be provided.

Hereinafter, embodiments according to the technical spirit of the present invention disclosure are described with reference to the accompanying drawings.

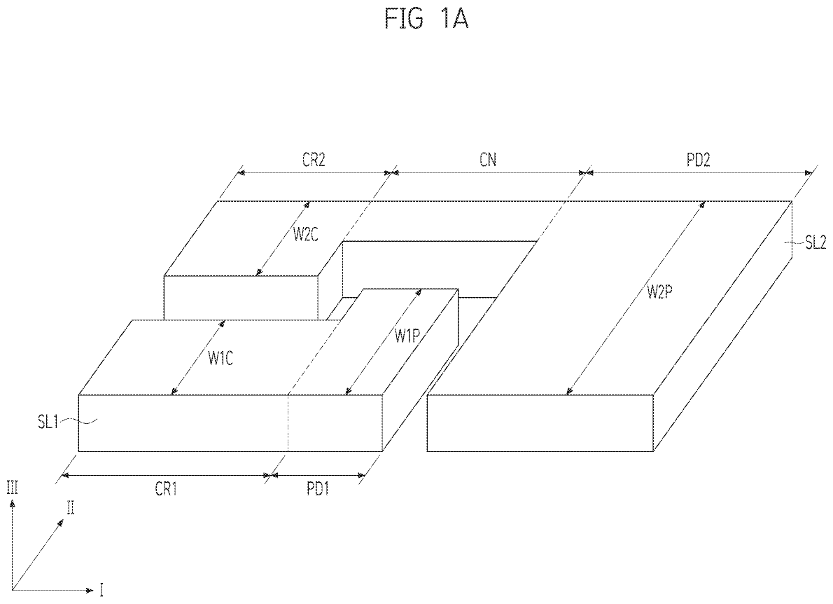

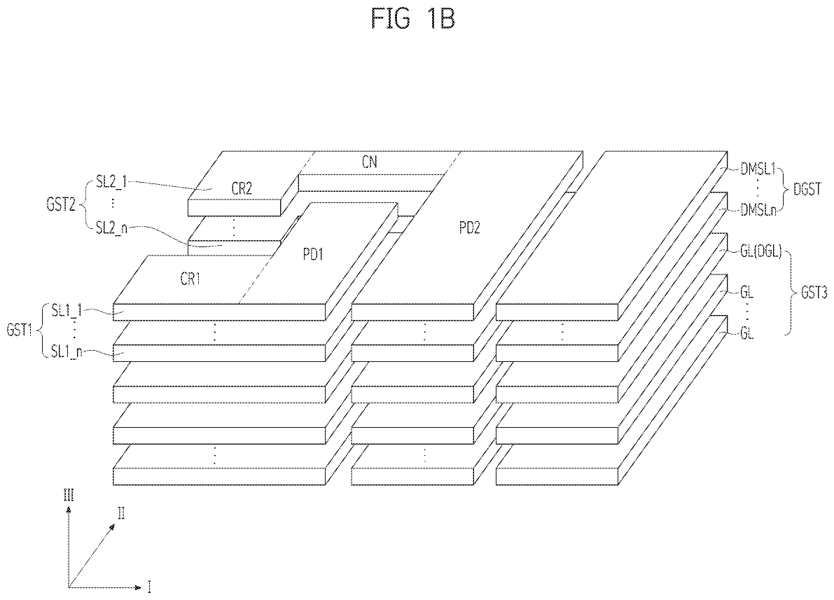

FIGS. 1A and 1B are diagrams illustrating a structure of a semiconductor device according to an embodiment of the present invention disclosure.

Referring to FIG. 1A, the semiconductor device may include a first selection line SL1 and a second selection line SL2. The first selection line SL1 may extend in a first direction I and may include a protrusion protruding in a second direction II. The second selection line SL2 may extend in the first direction I and may include a concave portion. The protrusion of the first selection line SL1 may be disposed in the concave portion of the second selection line SL2. The first selection line SL1 and the second selection line SL2 may be arranged in a form in which the protrusion and the concave portion are engaged. The second selection line SL2 may surround the protrusion of the first selection line SL1. The first selection line SL1 and the second selection line SL2 may be disposed at substantially the same level in a third direction III. Here, the first direction I and the second direction II may cross with each other. In some embodiments, the first direction I and the second direction II may cross at a right angle. The third direction III may be a direction orthogonal to a plane defined by the first direction I and the second direction II.

The first selection line SL1 may be a source selection line or a drain selection line. The first selection line SL1 may include a first cell region CR1 and a first pad region PD1. The first cell region CR1 and the first pad region PD1 may be adjacent in the first direction I. The first cell region CR1 and the first pad region PD1 may be in contact with each other in the first direction I. In the second direction II, the first cell region CR1 may have a first width W1C and the first pad region PD1 may have a first width W1P. In the second direction II, the width W1P of the first pad region PD1 may be greater than the width W1C of the first cell region CR1. The first cell region CR1 and the first pad region PD1 may each have a generally rectangular prism shape and may be formed adjacent to each other to form the first selection line SL1 to have an “L” shape

The second selection line SL2 may be a source selection line or a drain selection line. The second selection line SL2 may include a second cell region CR2 and a second pad region PD2. The second cell region CR2 and the second pad region PD2 may be connected to each other via a connection region CN In the second direction II, the second cell region CR2 may have a second width W2C and the second pad region PD2 may have a second width W2P. In the second direction II, the width W2P of the second pad region PD2 may be greater than the width W2C of the second cell region CR2. The width W2P of the second pad region PD2 may be greater than the width WP1 of the first pad region PD1.

The second selection line SL2 may further include the connection region CN which connects the second cell region CR2 and the second pad region PD2. The connection region CN may extend in the first direction I along a sidewall of the first pad region. In the second direction II, the connection region CN may have a width less than that of the second cell region CR2 and the second pad region PD2.

The first pad region PD1 may protrude toward the connection region CN between the second cell region CR2 and the second pad region PD2. In the second direction II, the width of the connection region CN may be smaller than the width W2C of the second cell region. A rectangular reception region may be defined between the second cell region CR2 and the second pad region PD2, and the first pad region PD1 may protrude into the rectangular reception region. Hence, the more the width of the connection region CN is decreased the more the first pad region PD1 can protrude into the rectangular reception region.

The first cell region CR1 and the second cell region CR2 may be a region where a memory string is disposed. The first and second pad regions PD1 and PD2 may be a region where a contact plug for transferring a bias (e.g., a bias voltage or bias current, typically a bias voltage) to a selection line is disposed. The first and second cell regions CR1 and CR2 may be adjacent in the second direction II. The first pad region PD1 and the connection region CN may be adjacent in the second direction II.

The first and second pad regions PD1 and PD2 may be adjacent in the first direction I. The first pad region PD1 may be disposed between the first cell region CR1 and the second pad region PD2 and between the second cell region CR2 and the second pad region PD2. Therefore, in the second direction II, the second pad region PD2 may have a width greater than a width obtained by adding the width of the first cell region CR1 and the width of the second cell region CR2.

Referring to FIG. 1B, the semiconductor device may include first and second gate structures GST1 and GST2. The first gate structure GST1 may include stacked first selection lines SL1_1 to SL1_n. The second gate structure GST2 may include stacked second selection lines SL2_1 to SL2_n, wherein n is an integer equal to or greater than 1.

The semiconductor device may further include at least one of a third gate structure GST3 and a dummy gate structure DGST. The third gate structure GST3 may include stacked gate lines GL. The gate lines GL may be word lines WL or a dummy gate line DGL. The dummy gate structure DGST may include stacked dummy selection lines DMSL1 to DMSLn.

Among the gate lines GL included in the third gate structure GST3, at least one uppermost gate line GL may be the dummy gate line DGL. The dummy gate line DGL may have a shape similar to that of at least one of the first selection lines SL1_1 to SL1_n, the second selection lines SL2_1 to SL2_n, and the gate line GL. The dummy gate line DGL may be disposed between the gate lines GL and the first selection lines SL1_1 to SL1_n, between the gate lines GL and the second selection lines SL2_1 to SL2_n, and between the gate lines GL and the dummy selection lines DMSL1 to DMSLn.

The first selection lines SL1_1 to SL1_n and the second selection lines SL2_1 to SL2_n may be stacked on the gate lines GL. The dummy selection lines DMSL1 to DMSLn may be stacked on the gate line GL. The dummy selection lines DMSL1 to DMSLn may be adjacent to the second selection lines SL2_1 to SL2_n in the first direction I. The second pad regions PD2 may be disposed between the dummy selection lines DMSL1 to DMSLn and the first pad regions PD1 and between the connection region CN and the dummy selection lines DMSL1 to DMSLn. In the second direction II, the dummy selection lines DMSL1 to DMSLn may have substantially the same width as the second pad region PD2.

According to the structure described above, the first pad region PD1 may have width greater than that of the first cell region CR1, and the second pad region PD2 may have width greater than that of the second cell region CR2. By selectively increasing the width of the first pad region PD1 and the second pad region PD2, the area where contact plugs connected to the first selection lines SL1_1 to SL1_n and the second selection lines SL2_1 to SL2_n are to be formed may be secured.

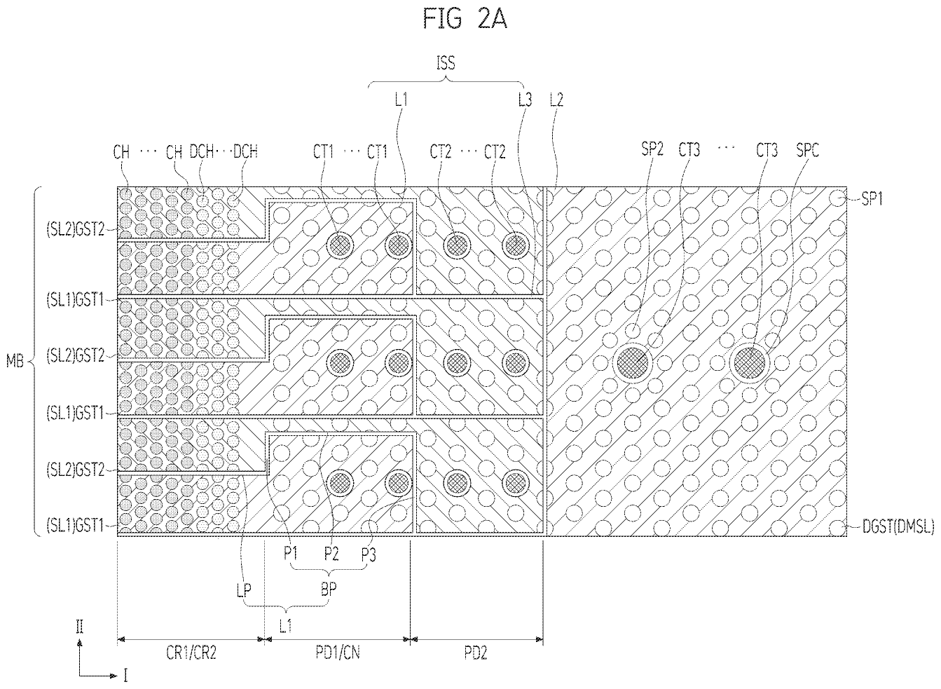

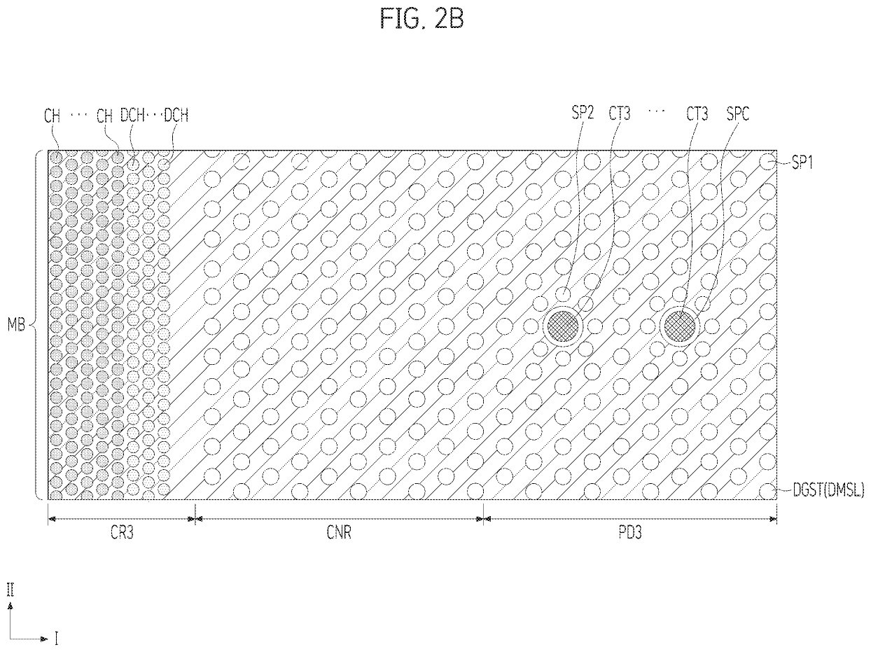

FIGS. 2A and 2B are diagrams illustrating a structure of a semiconductor device according to an embodiment of the present invention disclosure. Hereinafter, a description overlapping a content described above may be omitted.

Referring to FIG. 2A, the semiconductor device may include at least one of the first gate structure GST1, the second gate structure GST2, and the dummy gate structure DGST. The first gate structures GST1 and the second gate structures GST2 may be alternately arranged along the second direction II. The first gate structure GST1 and the second gate structure GST2 may be adjacent to the dummy gate structure DGST in the first direction I.

The first gate structure GST1 may include the stacked first selection lines SL1. The first selection line SL1 may include the first cell region CR1 and the first pad region PD1. A channel structure CH and a dummy channel structure DCH may be disposed in the first cell region CR1. A first contact plug CT1 may be disposed in the first pad region PD1. The number of first contact plugs CT1 may be equal to or greater than the number of first selection lines SL1. An insulating spacer SPC may surround a sidewall of the first contact plug CT1. The first contact plug CT1 may have a width (or diameter) greater than that of the channel structure CH. First supports SP1 may be disposed around the first contact plug CT1.

The second gate structure GST2 may include the stacked second selection lines SL2. The second selection line SL2 may include the second cell region CR2 and the second pad region PD2. The channel structure CH and the dummy channel structure DCH may be disposed in the second cell region CR2. A second contact plug CT2 may be disposed in the second pad region PD2. The number of second contact plugs CT2 may be equal to or greater than the number of second selection lines SL2. The insulating spacer SPC may surround a sidewall of the second contact plug CT2. The second contact plug CT2 may have a width greater than that of the channel structure CH. The first supports SP1 may be disposed around the second contact plug CT2.

The dummy gate structure DGST may include stacked dummy selection lines DMSL. The first supports SP1 and a third contact plug CT3 may be disposed in the dummy gate structure DGST. The insulating spacer SPC may surround a sidewall of the third contact plug CT3. The third contact plug CT3 may have a width greater than that of the channel structure CH. Second support SP2 may be disposed around the third contact plug CT3. In some embodiments, the second supports SP2 may be arranged along a circumference of a circular shape, an elliptical shape, a polygonal shape, or the like surrounding the third contact plug CT3. The first supports SP1 may be disposed around the second supports SP2. The second supports SP2 may have a width narrower than that of the first supports SP1.

The first gate structures GST1, the second gate structures GST2, and the dummy gate structure DGS may be isolated by an isolation structure ISS. The isolation structure ISS may include at least one of a first line portion L1, a second line portion L2, and a third line portion L3. The first line portion L1 may extend between the first gate structure GST1 and the second gate structure GST2. In some embodiments, the first line portion L1 may extend between the first gate structure GST1 and the second gate structure GST2 adjacent in the first direction I.

The first line portion L1 may include a straight line portion LP and a bent portion BP. The straight line portion LP may extend in the first direction I between the first cell region CR1 and the second cell region CR2. The bending portion BP may extend between the first pad region PD1 and the second pad region PD2. In some embodiments, the bending portion BP may include a first portion P1 extending between the second cell region CR2 and the first pad region PD1, a second portion P2 extending between the first pad region PD1 and the connection region CN, and a third portion P3 extending between the first pad region PD1 and the second pad region PD2. Each of the portions may have a straight line shape, and a bending point may be disposed between each of the portions.

The second line portion L2 may extend in the second direction II. The second gate structures GST2 and the dummy gate structure DGST may be separated from each other by the second line portion L2. The third line portion L3 may extend in the first direction I. The first gate structure GST1 and the second gate structure GST2 adjacent in the second direction II may be separated from each other by the third line portion L3.

Referring to FIG. 2B, the semiconductor device may further include the third gate structure GST3. The third gate structure GST3 may be disposed on or under the first gate structure GST1, the second gate structure GST2, and the dummy gate structure DGST. In some embodiments, the first gate structures GST1, the second gate structures GST2, and the dummy gate structure DGST may be disposed on the third gate structure GST3. The first cell region CR1 and the second cell region CR2 may be disposed on a third cell region CR3. The first pad region PD1, the connection region CN, and the second pad region PD2 may be disposed on the connection region CNR. The dummy gate structure DGST may be disposed on a third pad region PD3.

The third gate structure GST3 may include stacked word lines WL. The word line WL may include the third cell region CR3, a connection region CNR, and the third pad region PD3. The connection region CNR may connect the third cell region CR3 and the third pad region PD3. In the second direction II, the third cell region CR3, the connection region CNR, and the third pad region PD3 may have substantially the same width.

The channel structure CH and the dummy channel structure DCH may be disposed in the third cell region CR3. The first supports SP1 and the second supports SP2 may be disposed in the connection region CNR. The third contact plug CT3 may be disposed in the third pad region PD3. The insulating spacer SPC may surround the sidewall of the third contact plug CT3. The second supports SP2 may be disposed around the third contact plug CT3. The first supports SP1 may be disposed around the second supports SP2.

For reference, in the present embodiment, a case where a memory block MB includes three first gate structures GST1, three second gate structures GST2, and one third gate structure GST3 is described, but the number of first gate structures GST1 and the second gate structures GST2 included in the memory block MB may be changed. Similarly, the number of channel structures CH included in the memory block MB may be changed. In addition, the number of first line portions L1 and the third line portions L3 included in the isolation structure ISS may be changed.

According to the structure described above, the first pad region PD1 may have the width greater than that of the first cell region CR1. The second pad region PD2 may have the width greater than that of the second cell region CR2. Therefore, the first contact plug CT1 and the second contact plug CT2 may have a width greater than that of the channel structure CH.

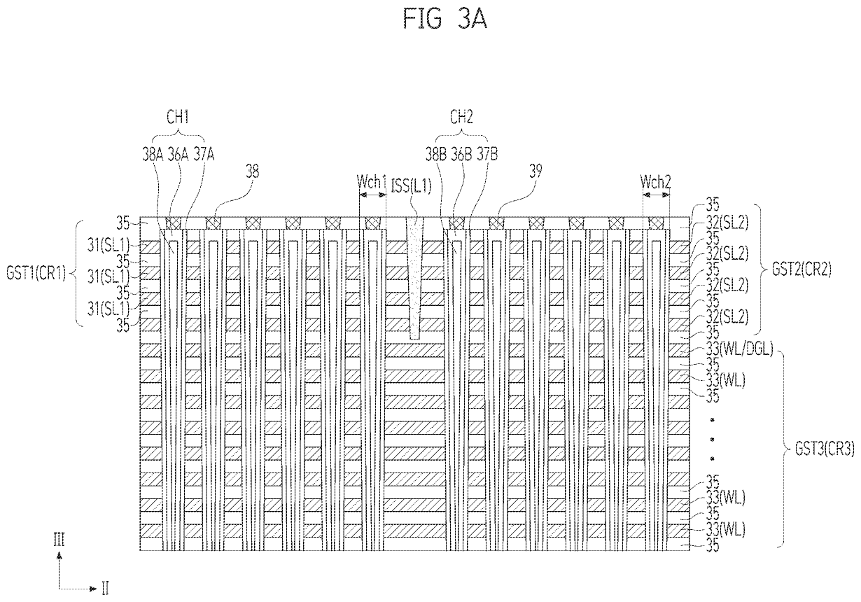

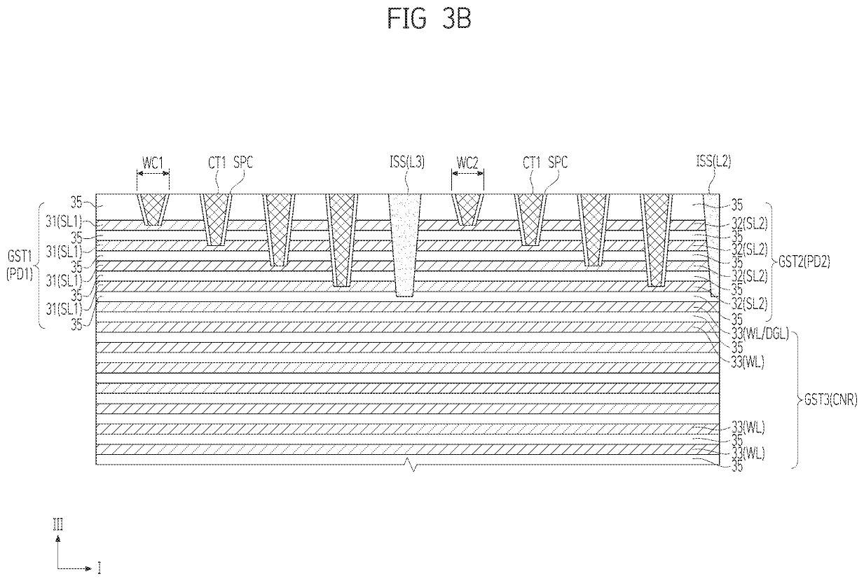

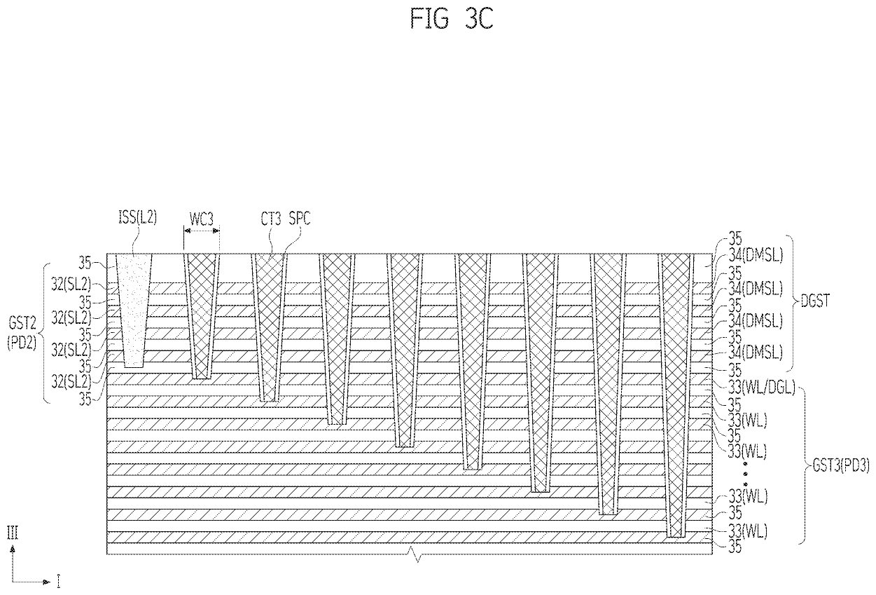

FIGS. 3A to 3C are diagrams illustrating a structure of a semiconductor device according to an embodiment of the present invention disclosure. Hereinafter, a description overlapping a content described above may be omitted.

Referring to FIG. 3A, the semiconductor device may include at least one of the first gate structure GST1, the second gate structure GST2, the third gate structure GST3, a first channel structure CH1, a second channel structure CH2, and the isolation structure ISS.

The first gate structure GST1 may include first conductive layers 31 and insulating layers 35 that are alternately stacked. The first conductive layers 31 may be the first selection line SL1, a drain selection line, or a source selection line. The first conductive layers 31 may include polysilicon, tungsten, molybdenum, or the like.

The second gate structure GST2 may include second conductive layers 32 and insulating layers 35 that are alternately stacked. The second conductive layers 32 may be the second selection line SL2, a drain selection line, or a source selection line. The second conductive layers 32 may include polysilicon, tungsten, molybdenum, or the like.

The third gate structure GST3 may include third conductive layers 33 and insulating layers 35 that are alternately stacked. The third conductive layers 33 may be word lines WL or dummy gate lines DGL. In some embodiments, at least the uppermost conductive layer may be the dummy gate line DGL, and the remaining third conductive layers 33 may be word lines WL. The third conductive layers 33 may include polysilicon, tungsten, molybdenum, or the like.

The first channel structure CH1 may extend through the first gate structure GST1 and the third gate structure GST3. The first channel structure CH1 may extend through the first cell region CR1 and the third cell region CR3. The first channel structure CH1 may include at least one of a first channel layer 36A, a first memory layer 37A, and a first insulating core 38A. The first memory layer 37A may include at least one of a tunneling layer, a data storage layer, and a blocking layer. The first channel structure CH1 may have a first width Wch1.

The second channel structure CH2 may extend through the second gate structure GST2 and the third gate structure GST3. The second channel structure CH2 may extend through the second cell region CR2 and the third cell region CR3. The second channel structure CH2 may include at least one of a second channel layer 36B, a second memory layer 37B, and a second insulating core 38B. The second memory layer 37B may include at least one of a tunneling layer, a data storage layer, and a blocking layer. The second channel structure CH2 may have a second width Wch2. The first width Wch1 and the second width Wch2 may be the same or substantially the same.

The first channel structures CH1 may be adjacent to the second channel structures CH2 in the second direction II. The isolation structure ISS may be disposed between the first channel structures CH1 and the second channel structures CH2. The first line portion L1 of the isolation structure ISS may be disposed between the first gate structure GST1 and the second gate structure GST2, and may isolate the first gate structure GST1 and the second gate structure GST2 from each other. The isolation structure ISS may be disposed on the third gate structure GST3. A via 39 may be connected to the first channel structures CH1 and the second channel structures CH2.

Referring to FIG. 3B, the semiconductor device may include at least one of the first gate structure GST1, the second gate structure GST2, the third gate structure GST3, the first contact plug CT1, the second contact plug CT2, the insulating spacer SPC, and the isolation structure ISS.

The first contact plugs CT1 may extend through the first gate structure GST1. The first contact plugs CT1 may extend at different depths in the first pad region PD1 and may be electrically connected to the first conductive layers 31, respectively, in a one to one correspondence. The first contact plugs CT1 may have a first width Wc1, and the first width Wc1 may be greater than at least one of the first width Wch1 of the first channel structure CH1 and the second width Wch2 of the second channel structure CH2.

The second contact plugs CT2 may extend through the second gate structure GST2. The second contact plugs CT2 may extend at different depths in the second pad region PD2. The second contact plugs CT2 may be electrically connected to the second conductive layers 32, respectively, in a one to one correspondence. The second contact plugs CT2 may have a second width Wc2. The second width Wc2 may be greater than at least one of the first width Wch1 of the first channel structure CH1 and the second width Wch2 of the second channel structure CH2.

The first contact plugs CT1 and the second contact plugs CT2 may be adjacent in the first direction I with the isolation structure ISS disposed between the first contact plugs CT1 and the second contact plugs CT2. The third line portion L3 of the isolation structure ISS may be disposed between the first gate structure GST1 and the second gate structure GST2, and may isolate the first gate structure GST1 and the second gate structure GST2 from each other. The isolation structure ISS may be disposed on the third gate structure GST3.

Referring to FIG. 3C, the semiconductor device may include at least one of the first gate structure GST1, the second gate structure GST2, the third gate structure GST3, the dummy gate structure DGST, the third contact plug CT3, the insulating spacer SPC, and the isolation structure ISS.

The dummy gate structure DGST may include fourth conductive layers 34 and insulating layers 35 that are alternately stacked in the third direction III. The fourth conductive layers 34 may be a dummy selection line DMSL. The fourth conductive layers 34 may include polysilicon, tungsten, molybdenum, or the like. The first gate structure GST1, the second gate structure GST2, and the dummy gate structure DGST may be disposed on the third gate structure GST3.

The third contact plugs CT3 may extend through the dummy gate structure DGST and the third gate structure GST3. The third contact plugs CT3 may pass through the dummy gate structure DGST and extend at different depths in the third pad region PD3. The third contact plugs CT3 may be electrically connected to the third conductive layers 33, respectively. The third contact plugs CT3 may have a third width Wc3, and the third width Wc3 may be greater than at least one of the first width Wch1 of the first channel structure CH1 and the second width Wch2 of the second channel structure CH2.

The third contact plugs CT3 and the second contact plugs CT2 may be adjacent in the first direction I with the isolation structure ISS disposed between the third contact plugs CT3 and the second contact plugs CT2. The second line portion L2 of the isolation structure ISS may be disposed between the dummy gate structure DGST and the second gate structure GST2, and may isolate the dummy gate structure DGST and the second gate structure GST2 from each other. The isolation structure ISS may be disposed on the third gate structure GST3.

According to the structure described above, the first to third gate structures GST1 to GST3 may not patterned in a step shape, and the first to third contact plugs CT1 to CT3 may be connected to the first to third conductive layers 31 to 33. Because the first to third contact plugs CT1 to CT3 extend through the first to third gate structures GST1 to GST3, the first to third contact plugs CT1 to CT3 may be formed in a width greater than that of the first and second channel structures CH1 and CH2. In addition, because the first and second pad regions PD1 and PD2 have a width greater than that of the first and second cell regions CR1 and CR2, the first to third contact plugs CT1 to CT3 having a relatively great width may be connected to the first to third conductive layers 31 to 33, respectively.

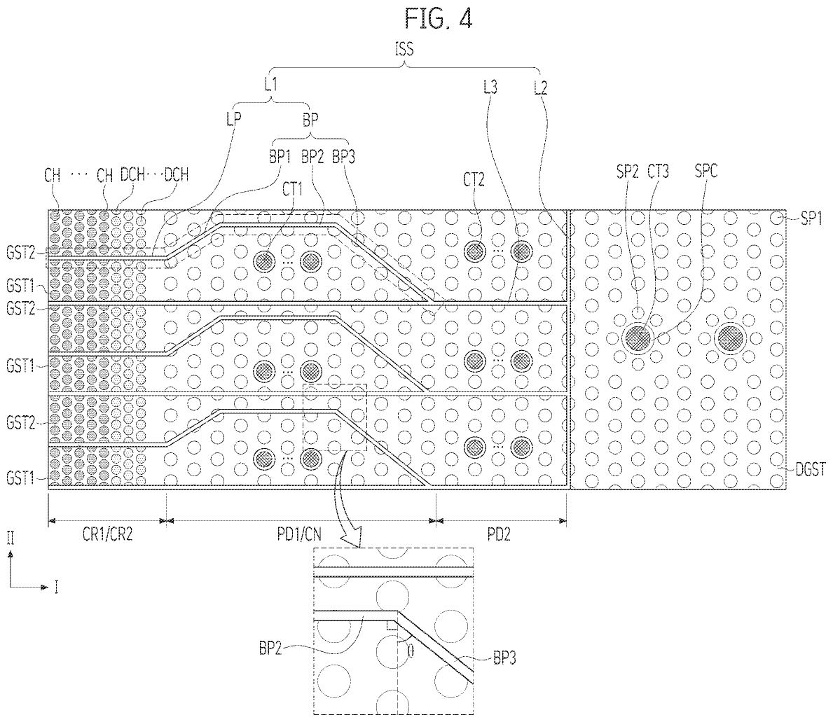

FIG. 4 is a diagram illustrating a structure of a semiconductor device according to an embodiment of the present invention disclosure. Hereinafter, a description overlapping a content described above may be omitted.

Referring to FIG. 4, the semiconductor device may include at least one of the first gate structure GST1, the second gate structure GST2, the dummy gate structure DGST, the first supports SP1, the second supports SP2, the first contact plugs CT1, the second contact plugs CT2, the third contact plugs CT3, the insulating spacers SPC, and the isolation structure ISS.

The isolation structure ISS may include the first line portion L1, the second line portion L2, and the third line portion L3. The second line portion L2 may extend in the second direction II, and the third line portion L3 may extend in the first direction I. The first line portion L1 may be disposed between the third line portions L3 adjacent in the second direction II, and may be connected to the third line portion L3 between the first contact plugs CT1 and the second contact plugs CT2.

The first line portion L1 may include a line portion LP and a bending portion BP. The line portion LP may extend in the first direction I, and the first cell region CR1 and the second cell region CR2 may be separated by the line portion LP. The bending portion BP may extend in a shape surrounding the first contact plugs CT1, and the first pad region PD1 having a width greater than that of the first cell region CR1 may be defined by the bending portion BP.

A shape of the bending portion BP may change according to a layout. In some embodiments, the bending portion BP may include a first portion BP1, a second portion BP2, and a third portion BP3. The first portion BP1 may extend in the second direction II or a diagonal direction, the second portion BP2 may extend in the first direction I, and the third portion BP3 may extend in the second direction II or the diagonal direction. Here, the second direction II may cross the first direction I at a right angle. The diagonal direction may cross the first direction I and the second direction II, and may cross the second direction II at an angle θ. The angle θ may be an acute angle. Here, the shape of the bending portion BP may change according to a distance between the third line portions L3 adjacent in the second direction II, a distance between the first contact plugs CT1 and the second contact plugs CT2, and the like.

Meanwhile, a shape of the isolation structure ISS may be variously changed. In some embodiments, the isolation structure ISS may have a shape in which the shape described with reference to FIGS. 2A and 2B and the shape described with reference to FIG. 4 are combined.

According to the structure described above, the first pad region PD1 and the second pad region PD2 may have the width greater than that of the first cell region CR1 and the second cell region CR2, and the second pad region PD2 may have the width greater than that of the first pad region PD1. Therefore, the area where the first contact plugs CT1 and the second contact plugs CT2 are to be disposed may be secured.

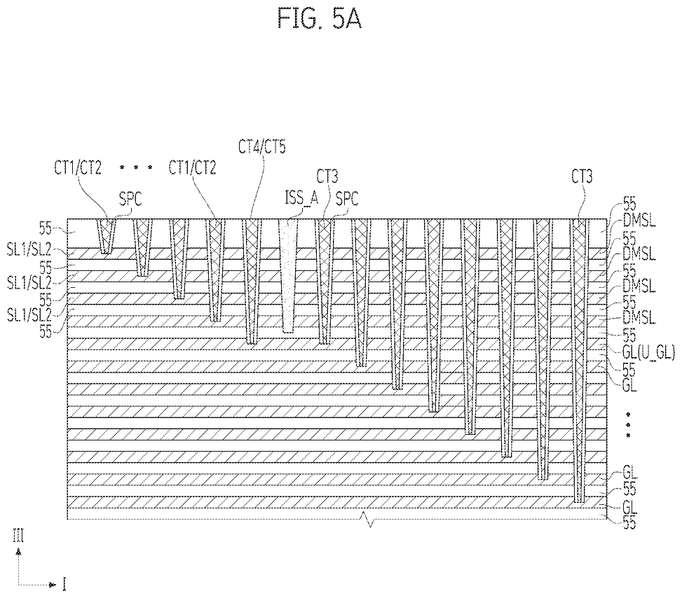

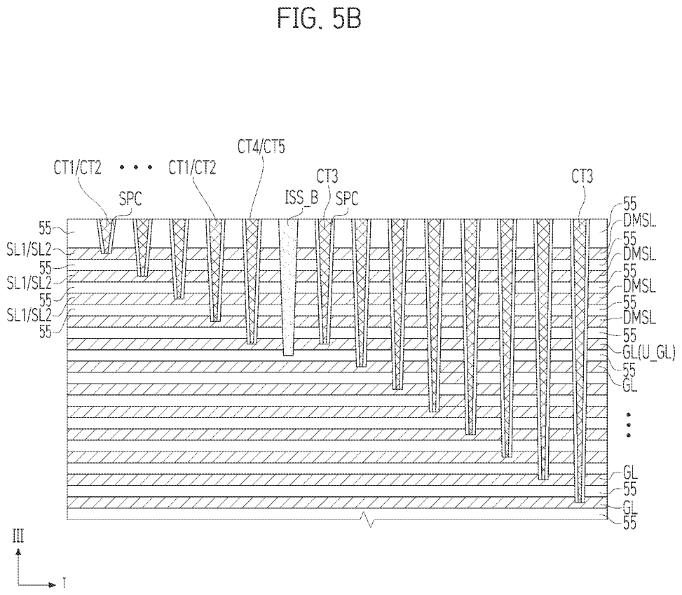

FIGS. 5A and 5B are diagrams illustrating a structure of a semiconductor device according to an embodiment of the present invention disclosure.

Referring to FIGS. 5A and 5B, the semiconductor device may include at least one of the first selection lines SL1, the second selection lines SL2, the dummy selection lines DMSL, the gate lines GL, insulating layers 55, the first contact plugs CT1, the second contact plugs CT2, the third contact plugs CT3, and isolation structures ISS_A and ISS_B.

The gate lines GL and the insulating layers 55 may be alternately stacked. The gate lines GL may be a word line, a selection line, a dummy gate line, and the like. In some embodiments, at least one uppermost gate line GL may be a dummy word line.

At least one of the first selection lines SL1 and the second selection lines SL2 may be stacked on the gate line GL. The first selection lines SL1 and the insulating layers 55 may be alternately stacked. The second selection lines SL2 and the insulating layers 55 may be alternately stacked. The first selection lines SL1 and the second selection lines SL2 may be a source selection line or a drain selection line.

The dummy selection lines DMSL may be stacked on the gate lines GL. The dummy selection lines DMSL and the insulating layers 55 may be alternately stacked. The dummy selection lines DMSL may be a dummy source selection line or a dummy drain selection line.

The first contact plugs CT1 may each extend at a different depth and connect to a different one of the first selection lines SL1. The first contact plugs CT1 may pass through one or more first selection lines SL1, except for the one connecting to the uppermost first selection line SL1. The second contact plugs CT2 may each extend to a different depth and connected to a different one of the second selection lines SL2. The second contact plugs CT2 may pass through one or more second selection lines SL2 except for the one connecting to the uppermost second selection line SL2. The third contact plugs CT3 may extend through to a different depth and pass through dummy selection lines DMSL to connect to a different one of the gate lines GL. The first contact plugs CT1 and the second contact plugs CT2 may be disposed on one side of the isolation structures ISS_A and ISS_B. The third contact plugs CT3 may be disposed on another side of the isolation structures ISS_A and ISS_B.

The semiconductor device may further include at least one of a fourth contact plug CT4 and a fifth contact plug CT5. The fourth contact plug CT4 may extend through the first selection lines SL1 and may be connected to an uppermost gate line U_GL. The fifth contact plug CT5 may extend through the second selection lines SL2 and may be connected to the uppermost gate line U_GL. The fourth and fifth contact plugs CT4 and CT5 may be disposed on one side of the isolation structures ISS_A and ISS_B. The fourth and fifth contact plugs CT4 and CT5 may have the same or substantially the same height as at least one of the third contact plugs CT3, and the third to fifth contact plugs CT3 to CT5 having the same or substantially the same height may be connected to the same gate line GL.

The fourth and fifth contact plugs CT4 and CT5 may be formed in consideration of cutting the gate line GL according to an uneven depth of the isolation structures ISS_A and ISS_B. During a manufacturing process, the isolation structures ISS_A, ISS_B may be formed at different depths due to a limitation on a process. Referring to FIG. 5A, the isolation structure ISS_A may isolate the first and second selection lines SL1 and SL2 and the dummy selection lines DMSL, and may be disposed on the gate lines GL. Referring to FIG. 5B, the isolation structure ISS_B may extend into the uppermost gate line GL and may pass through the uppermost gate line GL. Hence, the uppermost gate line U_GL may be isolated by the isolation structure ISS_B. The isolated uppermost gate lines U_GL may be insulated from each other. In this case, a bias transferred through the third contact plug CT3 may be transferred only to the uppermost gate line U_GL disposed on the other side of the isolation structure ISS_B and is not transferred to the uppermost gate line U_GL disposed on one side of the isolation structure ISS_B.

Therefore, the semiconductor device may further include at least one of the fourth and fifth contact plugs CT4 and CT5 in consideration of a depth change of the isolation structures ISS_A and ISS_B. The fourth contact plug may extend through the first selection lines SL1 and may be connected to the uppermost gate line U_GL. The fifth contact plug CT5 may extend through the second selection lines SL2 and may be connected to the uppermost gate line U_GL. In some embodiments, at least one fourth contact plug CT4 may be connected to at least one uppermost gate line GL. The fourth and fifth contact plugs CT4 and CT5 may transfer a bias to the uppermost gate line U_GL on one side of the isolation structures ISS_A and ISS_B. The third contact plugs CT3 may transfer a bias to the uppermost gate line U_GL on the other side of the isolation structures ISS_A and ISS_B.

According to the structures described above, in consideration of the depth change of the isolation structures ISS_A and ISS_B, the semiconductor device may further include at least one of the fourth and fifth contact plugs CT4 and CT5. Therefore, even though the uppermost gate line U_GL is cut by the isolation structure ISS_B, a bias may be transferred to the uppermost gate lines U_GL through the fourth and fifth contact plugs CT4 and CT5.

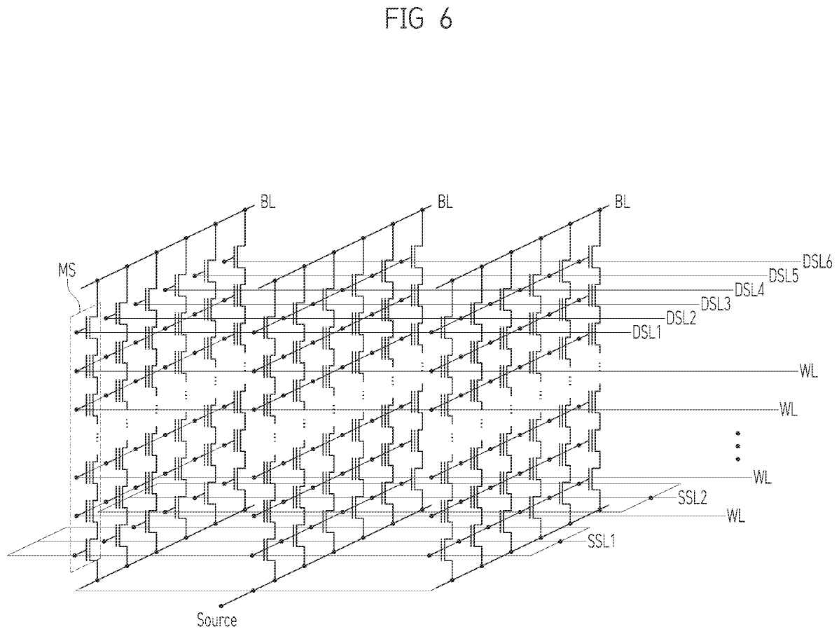

FIG. 6 is a circuit diagram illustrating a cell array structure of a semiconductor device according to an embodiment of the present invention disclosure.

Referring to FIG. 6, a cell array may include a plurality of memory strings MS. The plurality of memory strings MS may be connected between bit lines BL and a source line Source. Each memory string MS may include at least one drain selection transistor DST, a plurality of memory cells MC, and at least one source selection transistor SST. Each of the memory strings MS may further include at least one dummy memory cell connected between the drain selection transistor DST and the memory cells MC and/or between the source selection transistor SST and the memory cells MC.

Gate electrodes of the memory cells MC are connected to word lines WL. Word line voltages (a program voltage, a pass voltage, a read voltage, and the like) required for driving the transistors may be applied to each of the word lines WL. Gate electrodes of the drain selection transistors DST may be connected to drain selection lines DSL1 to DSL6. Gate electrodes of the source selection transistors SST may be connected to source selection lines SSL1 and SSL2.

According to the structure described above, the cell array may include a plurality of memory blocks, and each memory block may include a plurality of pages. The memory block may be a unit that performs an erase operation, and the page may be a unit that performs a program operation or a read operation.

Memory strings MS connected to the same bit line BL may be connected to different drain selection lines DSL0 to DSL6, respectively. The drain selection lines DSL0 to DSL6 may be electrically isolated by the isolation structures ISS, ISS_A, and ISS_B described above with reference to FIGS. 1A to 5B. Therefore, the drain selection lines DSL0 to DSL6 may be respectively driven, and the program operation or the read operation may be performed in a page unit.

Although embodiments according to the technical scope of the present invention disclosure have been described with reference to the accompanying drawings, this is only for describing an embodiment according to the concept of the present invention disclosure, and the present invention disclosure is not limited to the above-described embodiments. Within the scope of the present invention disclosure described in the claims, various forms of substitution, modification, and change of the embodiments will be possible by those skilled in the art to which the present invention disclosure belongs, and these also belong to the scope of the present invention disclosure.

What is claimed is:

1. A semiconductor device comprising:
a first gate structure including stacked first selection lines, each first selection line including a first cell region and a first pad region adjacent in a first direction;
a second gate structure including stacked second selection lines, each second selection line including a second cell region and a second pad region adjacent in the first direction;
first contact plugs extending through the first pad region and respectively connected to the first selection lines; and
second contact plugs extending through the second pad region and respectively connected to the second selection lines,
wherein in a second direction crossing the first direction, the first pad region has a width greater than that of the first cell region, and the second pad region has a width greater than that of the first pad region.

2. The semiconductor device of claim 1, wherein the first pad region is disposed between the first cell region and the second pad region.

3. The semiconductor device of claim 2, wherein the first pad region protrudes between the second cell region and the second pad region.

4. The semiconductor device of claim 1, wherein the first pad region and the second pad region are adjacent in the first direction.

5. The semiconductor device of claim 1,
wherein the second gate structure includes a connection region connecting the second cell region and the second pad region, and
wherein the first pad region protrudes toward the connection region.

6. The semiconductor device of claim 5,
wherein the first pad region protrudes into the second gate structure, and
wherein the second cell region, the connection region, and the second pad region surround the first pad region.

7. The semiconductor device of claim 1, further comprising:
an isolation structure extending between the first gate structure and the second gate structure.

8. The semiconductor device of claim 1, further comprising:
a dummy gate structure including stacked dummy selection lines; and
an isolation structure electrically isolating the first gate structure, the second gate structure, and the dummy gate structure from each other.

9. The semiconductor device of claim 8, wherein the isolation structure comprises:
a first line portion extending between the first gate structure and the second gate structure and including a bending portion; and
a second line portion extending between the second gate structure and the dummy gate structure.

10. The semiconductor device of claim 9, wherein the first line portion comprises:
a straight line portion extending between the first cell region and the second cell region; and
the bending portion extending between the first pad region and the second pad region.

11. The semiconductor device of claim 8, further comprising:
a third gate structure including stacked gate lines,
wherein the first gate structure, the second gate structure, the dummy gate structure, and the isolation structure are disposed on the third gate structure.

12. The semiconductor device of claim 11, further comprising:
third contact plugs extending through the dummy gate structure and the third gate structure and respectively connected to the gate lines.

13. The semiconductor device of claim 12, further comprising:
a fourth contact plug extending through the first gate structure and the third gate structure, wherein the fourth contact plug is connected to an uppermost gate line.

14. The semiconductor device of claim 13, wherein the uppermost gate line is a dummy word line.

15. The semiconductor device of claim 13, further comprising:
a fifth contact plug extending through the second gate structure and the third gate structure, wherein the fifth contact plugs are connected to the uppermost gate line.

16. The semiconductor device of claim 1, further comprising:
first supports extending through the first pad region and disposed around the first contact plugs; and
second supports extending through the second pad region and disposed around the second contact plugs.

17. The semiconductor device of claim 1, further comprising:
insulating spacers respectively surrounding sidewalls of the first contact plugs and the second contact plugs.

18. A semiconductor device comprising:
gate lines;
first selection lines stacked on the gate lines;
dummy selection lines stacked on the gate lines;
an isolation structure disposed between the first selection lines and the dummy selection lines and extending into an uppermost gate line among the gate lines;
first contact plugs extending into the first selection lines at different depths and respectively connected to the first selection lines;
third contact plugs extending through the dummy selection lines and respectively connected to the gate lines; and
a fourth contact plug extending through the first selection lines and connected to the uppermost gate line.

19. The semiconductor device of claim 18, further comprising:
second selection lines stacked on the gate lines; and
second contact plugs extending into the second selection lines at different depths and respectively connected to the second selection lines.

20. The semiconductor device of claim 19, wherein each of the first selection lines includes a first cell region and a first pad region having a width greater than that of the first cell region, and
each of the second selection lines includes a second pad region having a width greater than that of the first pad region.

21. The semiconductor device of claim 19, further comprising:
a fifth contact plug extending through the second selection lines and connected to the uppermost gate line.

22. The semiconductor device of claim 18, wherein the uppermost gate line is a dummy gate line.
